(19) United States
(12) Patent Application Publication
(10) Pub. No.: US 2025/0071882 A1
(43) Pub. Date: Feb. 27, 2025

(54) CONTROL UNIT

(71) Applicant: Hella GmbH & Co. KGaA, Lippstadt (DE)

(72) Inventors: Etienne Doyard, Toulouse (FR); Charles-Henry Feuillet, Toulouse (FR)

(21) Appl. No.: 18/944,295

(22) Filed: Nov. 12, 2024

Related U.S. Application Data
(63) Continuation of application No. PCT/EP2022/063058, filed on May 13, 2022.

(51) Int. Cl. H05K 1/02; H05K 1/14

(52) U.S. Cl. CPC H05K 1/0204; H05K 1/147; H05K 2201/042

(57) ABSTRACT

A control unit includes a first layer having a printed circuit board (PCB), a second layer having a PCB, and a solid member having a heatsink sandwiched in a space between the first layer and the second layer. The second layer is arranged, in a direction of gravity, above the first layer and is connected to the first layer via a flexible member carrying power tracks. The first layer is a power board and the second layer is a logic board. The solid member includes a number of holes to allow hot air to stream through the solid member.

### CROSS REFERENCE

This application claims priority to PCT Application No. PCT/EP2022/063058, filed May 13, 2022, the entirety which is hereby incorporated by reference.

### FIELD OF THE INVENTION

The present invention relates to a control unit for controlling a component of a machine, such as a motor of a vehicle, for example.

### BACKGROUND OF THE INVENTION

Control units get hot due to stream of electrical current, in particular in areas with high power flow and dense electrical units.

Modern control units use flexible PCB layers carrying power tracks that allow high current to flow between two rigid PCB members.

US 2019/0150269 A1 describes multiple rigid printed circuit boards (PCBs) connected via a flexible PCB layer, thereby forming a sandwich structure.

WO 2021 069061 A1 describes a heat-sink sandwiched between two rigid PCBs connected via a flexible PCB layer allowing high current to flow between the two rigid PCBs.

### BRIEF SUMMARY OF THE INVENTION

Against this background, there is a problem with thermal management in control units that are arranged in a sandwich structure due to very high currents streaming between particular layers of the sandwich structure.

In order to solve the above identified problem, according to a first aspect of the present invention, a control unit for controlling a component of a machine is disclosed herein. The control unit comprises a first layer comprising a printed circuit board (PCB), a second layer comprising a PCB, and a solid member comprising a heatsink sandwiched in a space between the first layer and the second layer.

The second layer is arranged, in a direction of gravity, above the first layer and is connected to the first layer via a flexible member carrying power tracks, wherein the first layer is a power board and the second layer is a logic board, and wherein the solid member comprises a number of holes configured to allow hot air to stream through the solid member.

The invention disclosed herein is based on the principle that holes are formed on a solid member between two PCBs, such that hot air trapped between a one of the PCBs and the solid member can pass through the solid member. Thus, the holes allow hot air that cannot stream in the heat sink, to stream through the solid member any away from a high current area with high thermal load.

According to an embodiment, the number of holes at least partially extends in an area covered by an element that extends from the heat sink towards the first layer.

Elements that extend from the solid member towards the first layer, i.e. downwards in a direction of gravity, form a heat trap for hot air rising from the first layer.

Thus, holes extending in an area that is covered by such an element provide for an efficient passage for thermal management of the control unit disclosed herein.

According to an embodiment, the number of holes at least partially extends in an area that is separated from the heat sink by an element arranged on the first layer.

Since elements arranged on the first layer, such as electronic components, for example, can block a passage for hot air streaming towards the heat sink, holes arranged in an area where hot air is trapped by such elements provide for an efficient passage for thermal management of the control unit disclosed herein.

According to an embodiment, the number of holes at least partially extends in an area that is separated from the heat sink by an element formed by the solid member.

Since elements formed by the solid member, such as housings for electronic components, for example, can block a passage for hot air streaming towards the heat sink, holes arranged in an area where hot air is trapped by such elements provide for an efficient passage for thermal management of the control unit disclosed herein.

According to an embodiment, the number of holes extends through the solid member and connects the space between the first layer and the solid member with a space between the second layer and the solid member.

By connecting the space between the first layer and the solid member with a space between the second layer and the solid member hot air can stream from the space between the first layer and the solid member into the space between the second layer and the solid member and cool off there or stream further away out of the control unit, for example.

According to an embodiment, the number of holes is arranged in an area at least partially covered by the flexible member.

Since the flexible member carries power tracks, the flexible member is prone to electrical and thermal load. Thus, by arranging the number of holes in an area at least partially covered by the flexible member, hot air generated by the power tracks of the flexible member and/or electronic components arranged near the flexible member is allowed to stream through the holes away from the flexible member, thereby reducing the thermal load in the flexible member and the control unit in total.

According to an embodiment, the number of holes is arranged between the heat sink and the flexible member.

Since hot air generated by the power units of the first layer accumulates between the heat sink and the flexible member, holes arranged in this area allow this hot air to stream through the holes away from the flexible member, thereby reducing the thermal load in the flexible member and the control unit in total.

According to an embodiment, the solid member comprises a plurality of receptors for receiving at least one element, wherein at least on hole of the number of holes extends in an area between particular receptors of the plurality of receptors.

Arranging the holes in an area between particular receptors secures that air streaming in an area covered by an electronic component received by the receptors is able to stream outside the area, thereby reducing the thermal load in the flexible member and the control unit in total.

According to an embodiment, the second layer comprises a number of holes configured to allow hot air streaming through the number of holes of the solid member to stream through the second layer in an environment outside the control unit.

Additional holes in the second layer provide for a thermal passage for hot air streaming through the holes of the solid member, thereby reducing the thermal in the control unit.

According to a second of the present invention, a machine, such as vehicle, for example, is disclosed herein. This machine comprises an embodiment of the control unit disclosed herein.

### BRIEF DESCRIPTION OF THE DRAWINGS

Reference is now made more particularly to the drawings, which illustrate the best presently known mode of carrying out the invention and wherein similar reference characters indicate the same parts throughout the views.

FIG. 1 illustrates a control unit according to an embodiment.

FIG. 2 illustrates a solid member of the control unit according to FIG. 1.

FIG. 3 illustrates a machine according to an embodiment.

### DETAILED DESCRIPTION OF THE DRAWINGS

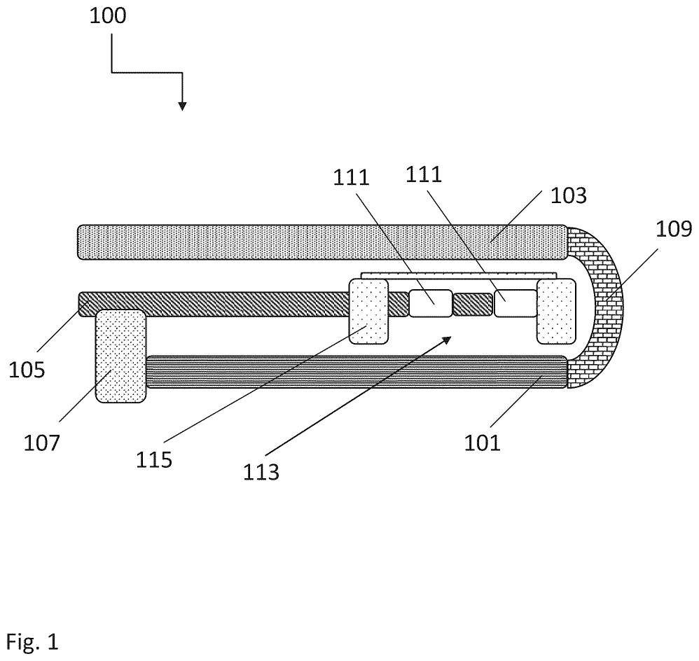

In FIG. 1, a control unit 100 is shown. The control unit 100 comprises a first layer 101 comprising a printed circuit board (PCB), a second layer comprising 103 a PCB, and a solid member 105 comprising a heatsink 107 sandwiched in a space between the first layer 101 and the second layer 103.

The second layer 103 is arranged, in a direction of gravity, above the first layer 101 and is connected to the first layer 101 via a flexible member 109 carrying power tracks.

The first layer 101 is a power board and the second layer 103 is a logic board.

The solid member 105 comprises a number of holes 111 configured to allow hot air to stream through the solid member 105. Thus, hot air streaming in an area 113 covered by a structural element 115 is not trapped in the area 113 but can stream through holes 111, thereby reducing the thermal load on the components of the control unit, in particular on the components of the power board.

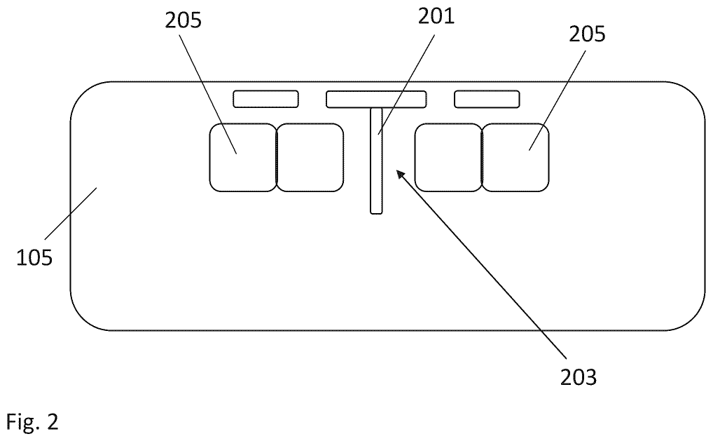

In FIG. 2 the solid member 105 is shown in detail. As can be seen from FIG. 2, a particular hole 201 extends in an area 203 between receptors 205 for receiving an element, such as an electronic component, for example. Thus air streaming in the area 203 can travel through hole 201 away from the element, thereby reducing the thermal load on the element.

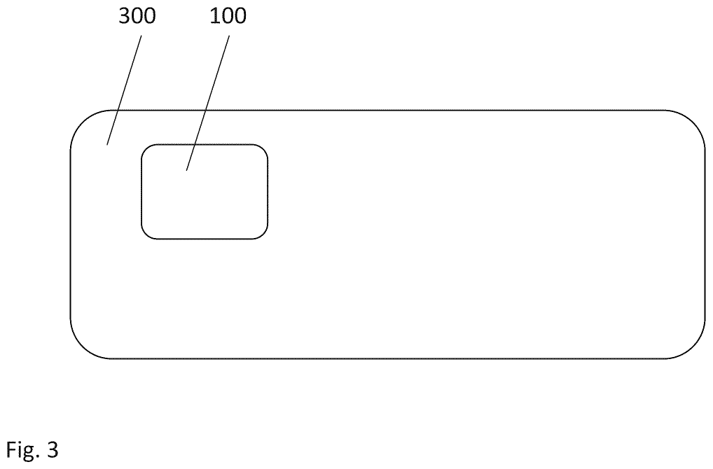

In FIG. 3 a machine 300 is shown. The machine 300 comprises the control unit 100 according to FIG. 1. Since control unit 100 is not prone for thermal failures machine 300 is very reliable.

### LIST OF REFERENCE SIGNS

100 control unit
101 first layer
103 second layer
105 solid member
107 heat sink
109 flexible member
111 hole
113 area
115 structural element
201 hole
203 area
205 receptor
300 machine

1. A control unit for controlling a component of a machine, the control unit comprising:
a first layer including a printed circuit board (PCB);
a second layer including a PCB;
a solid member including a heatsink sandwiched in a space between the first layer and the second layer,
wherein the second layer is arranged, in a direction of gravity, above the first layer and is connected to the first layer via a flexible member carrying power tracks,
wherein the first layer is a power board and the second layer is a logic board, and
wherein the solid member includes a plurality of holes to allow hot air to stream through the solid member.

2. The control unit according to claim 1, wherein the plurality of holes at least partially extends into an area covered by an element that extends from the solid member towards the first layer.

3. The control unit according to claim 1, wherein the plurality of holes at least partially extends into an area that is separated from the heat sink by an element arranged on the first layer.

4. The control unit according to claim 1, wherein the plurality of holes at least partially extends into an area that is separated from the heat sink by an element formed by the solid member.

5. The control unit according to claim 1, wherein the plurality of holes extends through the solid member and connects the space between the first layer and the solid member with a space between the second layer and the solid member.

6. The control unit according to claim 1, wherein the plurality of holes is arranged in an area at least partially covered by the flexible member.

7. The control unit according to claim 1, wherein the plurality of holes is arranged between the heat sink and the flexible member.

8. The control unit according to claim 1, wherein the solid member includes a plurality of receptors for receiving at least one element, and
wherein at least one hole of the plurality of holes extends into an area between particular receptors of the plurality of receptors.

9. The control unit according to claim 1, wherein the second layer includes a plurality of holes to allow hot air streaming through the plurality of holes of the solid member to stream through the second layer in an environment outside the control unit.

10. A machine comprising a control unit according to claim 1.
